(19) United States
(12) Patent Application Publication
(10) Pub. No.: US 2013/0105809 A1
(43) Pub. Date: May 2, 2013

(54) LIGHT EMITTING DIODE CHIP WITH HIGH HEAT-DISSIPATION EFFICIENCY

(71) Applicant: HSIU-PING CHANG, Chu-Nan (TW)

(72) Inventor: HSIU-PING CHANG, Chu-Nan (TW)

(73) Assignee: FOXSEMICON INTEGRATED TECHNOLOGY, INC., Chu-Nan (TW)

(21) Appl. No.: 13/336,004

(22) Filed: Dec. 23, 2011

(30) Foreign Application Priority Data
Oct. 26, 2011 (TW) 100138793

(51) Int. Cl. H01L 33/62

(52) U.S. Cl. 257/76; 257/99; 257/103; 257/E33.064; 257/E33.025

(57) ABSTRACT

A light emitting diode chip includes a substrate and an epitaxial layer formed on the substrate. The substrate is made of indium tin oxide (ITO) and has nano hydrogenation of SiC (SiC:H) particles doped therein. The substrate functions as a first electrode for the light emitting diode chip. The epitaxial layer consists of a first conductive type semiconductor material layer, a light-emitting layer and a second conductive type semiconductor material layer. A second electrode is formed on the second conductive type semiconductor material layer.

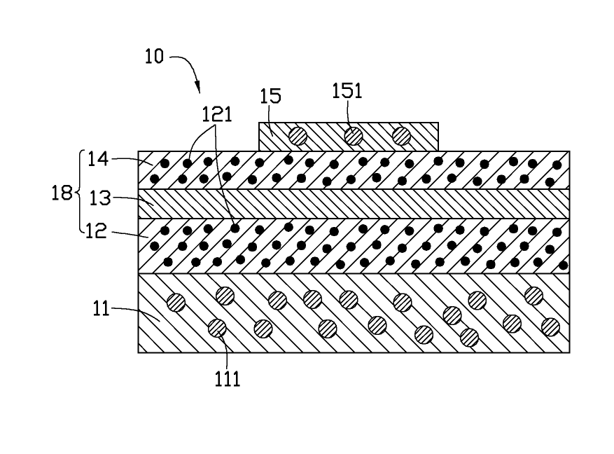

### BACKGROUND

1. Technical Field

The disclosure relates to light emitting diode chips with high heat-dissipation efficiency.

2. Description of the Related Art

Light emitting diode chips, specifically the electrical and optical characteristics and lifespan thereof, are easily influenced by temperature. High working temperatures can deteriorate internal quantum efficiency of the chip and shorten the lifespan thereof. Furthermore, resistance of the semiconductor generates a negative temperature coefficient and tends to be reduced with an increase in the working temperature. Such reduced resistance correspondingly results in stronger current at given voltages as well as the generation of excessive heat. If the excessive heat is not effectively dissipated, heat accumulation can lead to deterioration of the light emitting diode chip.

What is needed, therefore, is an LED chip which can overcome the above-mentioned problems.

### BRIEF DESCRIPTION OF THE DRAWINGS

Many aspects of the present light emitting diode chips can be better understood with reference to the following drawing. The components in the drawing are not necessarily drawn to scale, the emphasis instead being placed upon clearly illustrating the principles of the present light emitting diode chips. Moreover, in the drawing, like reference numerals designate corresponding parts throughout the several views.

The only drawing is a cross-sectional view of a light emitting diode chip in accordance with an embodiment of the present disclosure.

### DETAILED DESCRIPTION

An embodiment of a light emitting diode chip 10 in accordance with the present disclosure is described in detail here with reference to the only drawing.

Referring to the only drawing, a light emitting diode chip 10 in accordance with the embodiment includes a substrate 11, a first conductive type semiconductor material layer 12 on the substrate 11, a light-emitting layer 13 on the first conductive type semiconductor material layer 12, a second conductive type semiconductor material layer 14 on the light-emitting layer 13, and an electrode 15 on the second conductive type semiconductor material layer 14.

The material of the substrate 11 is indium tin oxide (ITO), with a plurality of nano hydrogenation of SiC (SiC:H) particles 111 evenly doped therein. A diameter of each nano hydrogenation of SiC particle 111 ranges from 20 nanometers to 200 nanometers.

Due to the nano hydrogenation of SiC (SiC:H) is transparent and has good heat transfer efficiency, heat from the light-emitting layer 13 is effectively dissipated by the substrate 11 to the outside of the light emitting diode chip 10, thereby heat-dissipation efficiency of the light emitting diode chip 10 is optimized, deterioration of the light emitting diode chip 10 can be avoided, and high internal quantum efficiency of the light emitting diode chip 10 can be achieved. Moreover, the nano hydrogenation of SiC has good electric conductivity, which is advantageous for the distribution and transfer of the current that flows in the substrate 11. In addition, because of the ITO and the nano hydrogenation of SiC both are transparent, light from the light-emitting layer 13 can be refracted easily by the substrate 11 and the nano hydrogenation of SiC particles 111 doped therein to emit out.

The first conductive type semiconductor material layer 12, the light-emitting layer 13 and the second conductive type semiconductor material layer 14 are successively formed on the substrate 11. In the present embodiment, the first conductive type semiconductor material layer 12 is an n-type semiconductor layer, and can be made of n-type III-V semiconductor, such as n-GaN, n-InP, n-GaInP or n-AlInGaP. The second conductive type semiconductor material layer 14 is a p-type semiconductor layer. Alternatively, the first conductive type semiconductor material layer 12 can be a p-type semiconductor layer and the second conductive type semiconductor material layer 14 can be an n-type semiconductor layer. A current is applied into the first conductive type semiconductor material layer 12 and the second conductive type semiconductor material layer 14, and accordingly the light-emitting layer 13 can emit light by a recombination of electrons and holes in the light-emitting layer 13.

The first conductive type semiconductor material layer 12 and the second conductive type semiconductor material layer 14 may have another nano materials 121 doped therein. The nano materials 121 are selected from a group of silicon oxide, silicon nitride, aluminum oxide, gallium oxide and boron nitride, which have good heat transfer efficiency to accordingly dissipate heat accumulated in the first conductive type semiconductor material layer 12 and the second conductive type semiconductor material layer 14. Alternatively, the nano materials 121 may be only doped in the first conductive type semiconductor material layer 12 or the second conductive type semiconductor material layer 14.

When the electrons from the first conductive type semiconductor material layer 12 and the holes from the second conductive type semiconductor material layer 14 are recombined in the light-emitting layer 13, light emits out and at the same time heat is generated. The heat generated from the light-emitting layer 13 will be dissipated upwardly and downwardly to accumulate at the first conductive type semiconductor material layer 12 and the second conductive type semiconductor material layer 14. Because the nano materials 121 doped in the first conductive type semiconductor material layer 12 and the second conductive type semiconductor material layer 14 have good heat transfer efficiency, heat accumulated in the first conductive type semiconductor material layer 12 and the second conductive type semiconductor material layer 14 can be dissipated efficiently.

The electrode 15 is formed on the second conductive type semiconductor material layer 14, which is made of gold, copper or other metals with good electrical conducting properties and bonding capability. The electrode 15 further has a second nano materials 151 disputed therein for improving the heat transfer efficiency of the light emitting diode chip 10. The second nano materials 151 can be transparent hydrogenation of SiC (SiC:H) materials, silicon oxide, silicon nitride, aluminum oxide, gallium oxide and boron nitride, or other materials with good heat transfer efficiency.

As described above, the substrate 11 and the electrode 15 are respectively attached on the top and bottom of an epitaxial layer 18 consisting of the first conductive type semiconductor material layer 12, the light-emitting layer 13 and the second conductive type semiconductor material layer 14. The substrate 11 is made of indium tin oxide (ITO) and has good electric conductivity which can efficiently spread the current applied thereto over an entire area of the substrate 11. Thus a uniformly distributed electrical current can be applied to the first conductive type semiconductor material layer 12, so the substrate 11 can be suitably used as another electrode of the light emitting diode chip 10 in addition to the electrode 15. The substrate 11 and the electrode 15 can corporately provide power from an external electrical power to the epitaxial layer 18 consisting of the first conductive type semiconductor material layer 12, the light-emitting layer 13 and the second conductive type semiconductor material layer 14. Therefore, the light emitting diode chip 10 is simple comparing with a conventional chip. In addition, because of the substrate 11 is transparent, light from the epitaxial layer 18 can freely pass through the substrate 11 to emit out, so that the output light efficiency of the light emitting diode chip 10 can be improved.

While certain embodiments have been described and exemplified above, various other embodiments from the foregoing disclosure will be apparent to those skilled in the art. The disclosure is not limited to the particular embodiments described and exemplified but is capable of considerable variation and modification without departure from the scope of the appended claims.

What is claimed is:

1. A light emitting diode chip comprising:
a substrate made of indium tin oxide (ITO) and having a plurality of nano hydrogenation of SiC (SiC: H) particles doped therein, the substrate being configured as an electrode for the light emitting diode chip; and
an epitaxial layer formed on the substrate and consisted of a first conductive type semiconductor material layer, a light-emitting layer and a second conductive type semiconductor material layer.

2. The light emitting diode chip of claim 1, wherein a diameter of each nano hydrogenation of SiC particle ranges from 20 nanometers to 200 nanometers.

3. The light emitting diode chip of claim 1, wherein the first conductive type semiconductor material layer is an n-type semiconductor layer made of n-GaN, n-InP, n-GaInP, or n-AlInGaP, and the second conductive type semiconductor material layer is a p-type semiconductor layer.

4. The light emitting diode chip of claim 1, wherein the first conductive type semiconductor material layer is a p-type semiconductor layer, and the second conductive type semiconductor material layer is an n-type semiconductor layer made of n-GaN, n-InP, n-GaInP, or n-AlInGaP.

5. The light emitting diode chip of claim 1, wherein the first conductive type semiconductor material layer has a second nano material doped therein, the second nano material is selected from a group consisting of silicon oxide, silicon nitride, aluminum oxide, gallium oxide and boron nitride.

6. The light emitting diode chip of claim 1, wherein the second conductive type semiconductor material layer has a second nano material doped therein, the second nano material is selected from a group consisting of silicon oxide, silicon nitride, aluminum oxide, gallium oxide and boron nitride.

7. The light emitting diode chip of claim 1, further comprising another electrode formed on the second conductive type semiconductor material layer of the epitaxial layer, the another electrode has a third nano material disputed therein for improving the heat transfer efficiency of the light emitting diode chip.

8. The light emitting diode chip of claim 7, wherein the third nano material is transparent hydrogenation of SiC.

9. The light emitting diode chip of claim 7, wherein the third nano material is selected from a group consisting of silicon oxide, silicon nitride, aluminum oxide, gallium oxide and boron nitride.
